(19) United States
(12) Patent Application Publication
(10) Pub. No.: US 2026/0120735 A1
(43) Pub. Date: Apr. 30, 2026

(54) SIDE-BAND MEMORY INTERFACE

(71) Applicant: Intel Corporation, Santa Clara, CA (US)

(72) Inventors: Mitchell DIAMOND, Shrewsbury, MA (US); Stephen MOREIN, San Jose, CA (US); Tina C TOUPAL, Portland, OR (US); William LEE, Sherwood, OR (US); Shamsul ABEDIN, Portland, OR (US)

(21) Appl. No.: 19/426,132

(22) Filed: Dec. 19, 2025

Related U.S. Application Data
(60) Provisional application No. 63/827,023, filed on Jun. 20, 2025.

(51) Int. Cl. G11C 8/16

(52) U.S. Cl. CPC G11C 8/16

(57) ABSTRACT

An apparatus includes a memory, comprising a plurality of stacked memory layers, each stacked memory layer comprising a plurality of memory cells; a memory controller, coupled to the memory along a first signal path, and configured to read a bit from, or store a bit on, a memory cell of the plurality of memory cells; and a logic unit, coupled to the memory via a second signal path, different from the first signal path; wherein the logic unit is configured to read a stored value from the memory, or to save a value to the memory, using the second signal path.

### CROSS-REFERENCE TO RELATED APPLICATIONS

This application claims priority to U.S. provisional application 63/827,023, filed on Jun. 20, 2025, the entire contents of which are incorporated by reference.

### BACKGROUND

Computer memory may come in any of a variety of different forms, such as, but not limited to, dual in-line memory modules (DIMMs), chiplets, or chip memory. Most interactions with a memory are performed through a memory controller. That is, memory is not generally directly accessed outside of (e.g., without going through) the memory controller.

In some circumstances, it may be desirable to directly access the memory outside of (e.g., without going through) the memory controller. For example, it may be desirable to access the memory outside of the memory controller during debugging operations or when gathering telemetry data. In particular, this may be advantageous when it is desired to access the memory without interrupting the memory controller or the flow of data between the memory controller and the memory. Moreover, debugging operations may be aided by accessing the memory without involving the memory controller in situations in which one or more portions of the path from the memory controller to the memory are malfunctioning.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the disclosure. In the following description, various exemplary embodiments of the disclosure are described with reference to the following drawings, in which:

FIG. 1 depicts an apparatus according to an embodiment;

FIG. 2 depicts an optional configuration of a memory layer of the plurality of memory layers of the package;

FIG. 3 depicts a system with multiple memory cubes; and

FIG. 4 depicts a method.

### DESCRIPTION

The following detailed description refers to the accompanying drawings that show, by way of illustration, exemplary details and embodiments in which aspects of the present disclosure may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As used herein, “memory” is understood as a computer-readable medium (e.g., a non-transitory computer-readable medium) in which data or information can be stored for retrieval. References to “memory” or “stacked memory” included herein may be directed in particular to memory arranged in a multi-layer vertical stack. In some configurations, this may be understood as a memory cube.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

In some configurations, it may be desirable to add a side-band interface to a memory. A side-band interface as used herein may describe a communication pathway, which may be used, for example, in networking or embedded systems, and that is separate from a main data path. In the context of memory, a side-band interface may be understood as an interface to connect with the memory that is different or distinct from the pathway between the memory controller and the memory. The side-band interface may permit any number of out-of-band management or control functions, while allowing for communication and control of a device or system without interfering with its primary data traffic. The side-band interface for a memory as described herein may permit access to the memory, may allow for poll telemetry, may permit the performance of debugging operations, or may permit the performance of management operations without going through other components which could also have issues (e.g., malfunctions, suboptimal behavior, etc.) while debugging, or direct management of the memory.

One possible and non-limiting implementation of a side-band interface for memory is a single wire interface that is implemented as an open drain connection to multiple taps within the memory structure. In a situation in which multiple slices of memory are used (e.g., in a stacked memory), a logic unit may communicate over the single wire interface using a predetermined protocol, such as a single-wire protocol. Of note, the single wire connection (or optionally a multiple-wire connection, such as a twisted pair) may be from the logic unit and through each layer of the memory stack. In this manner, any bit sent from the logic unit may reach each layer of the memory stack, and any bit sent by any layer of the memory stack may reach the logic unit. That is, if one endpoint wants to talk, it may write onto the wire and then read back what was written. Collision avoidance may be implemented with simple listening techniques, such that if a first endpoint detects that it overlapped with a second endpoint's communication, the first endpoint may be configured such that it does not subsequently send information. Of note, the various layers of the stacked memory layers may be configured to send or receive data over the second signal path without a multiplexer.

As described above, one possible use of the side-band interface as disclosed herein is the example of telemetry access, which allows the controller on the board to collect telemetry from memory over this network such as power, thermal performance, and reliability, availability, and serviceability (RAS), etc. issues. The skilled person will appreciate the various kinds of memory telemetry available, but for illustrative purposes, a non-limiting list of possible telemetry functions may include any of heap memory usage, such as tracking an amount of memory used by objects in a heap; non-heap memory usage, such as Monitoring memory used by code and other resources outside the heap; garbage collection frequency and duration, such as analyzing how often the garbage collector runs and how long it takes to free up memory; memory allocation and deallocation patterns, such as understanding how memory is being allocated and released by the application; and memory usage by different processes or components, such as identifying which parts of the system are consuming the most memory.

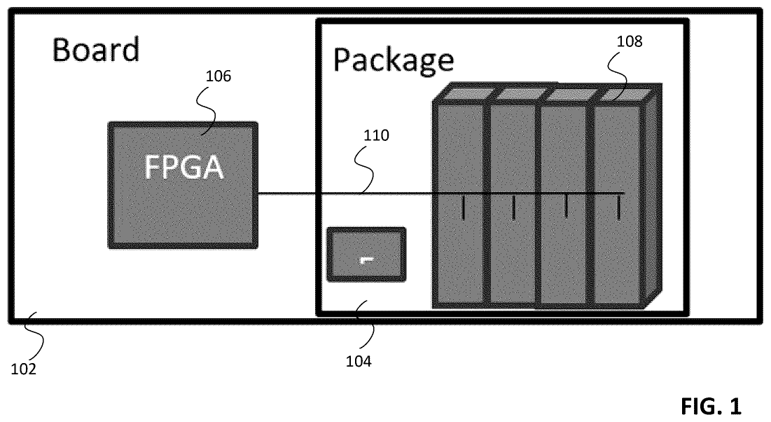

FIG. 1 depicts an apparatus according to an embodiment. In this figure, the apparatus includes a circuit board 102 and a package 104. The circuit board 102 includes a logic unit 106 (labeled for demonstrative purposes as a field programmable gate array (FPGA)), which may be or include an FPGA, a controller, a processor, or another circuit capable of generating and sending signals to the package 104 and/or of receiving signals from the package 104. The logic unit 106 may be configured to convert package commands to commands for a protocol for communication along the second wire interface or vice versa.

The logic unit 106, for example, may change packet based commands to single-wire interface commands, and from single-wire interface commands to packet commands, or in a configuration with a twisted wire-pair, from packet based command to twisted-wire interface commands and vice versa. The package 104 may include a memory 108, which may be a stacked memory array. In this manner, the memory 108 may include a plurality of memory layers, which may be stacked upon one another. In one embodiment, these memory layers may be vertically stacked such that they approximate a cubic form. The memory 108 may be coupled to a memory controller (not pictured) along a first signal path (not pictured). The memory 108 may be coupled to the logic unit 106 along a second signal path 110, which is distinct from the first signal path. In this manner, “distinct” means that the first signal path and the second signal path 110 are not electrically conductively coupled, such that a signal sent along the first signal path is not directly interfered with by a signal along the second signal path. Alternatively or additionally, the second signal path may be configured such that the logic unit 106 can communicate with the memory 108 without communicating through the memory controller.

The second signal path 110 may be a single wire signal path. In this manner, the logic unit 106, the second signal path 110, and the memory 108 may be configured to communicate according to a single wire protocol. The single wire protocol may be or include 1-Wire, Single Wire Protocol, Inter-Integrated Circuit Protocol (I3C), or Inter-Integrated Circuit Protocol (I2C), although this list is not intended to be exclusive.

In an alternative configuration, the second signal 110 path may be or include a twisted wire pair. In this manner, the logic unit 106, the second signal path 110, and the memory 108 may be configured to utilize a suitable protocol for a twisted wire pair, which may optionally include Ethernet.

In an optional configuration, and when the second signal path is configured as a signal-wire interface, the second signal path may be configured with an open drain configuration. In this manner, the single-wire may be coupled to a pull-up resistor, which may be configured to raise or pull-up a voltage at the single-wire interface to high reference voltage (the actual voltage of which may be configurable for the given implementation). The single-wire interface may be coupled to a transistor (e.g., a MOSFET), whose drain or output is coupled to a low reference (e.g., a ground or a voltage that is otherwise lower than the high reference voltage). The logic unit may be configured to control the gate of the transistor to selectively connect the single-wire interface to the low reference voltage, thereby selectively alternating the voltage at the single-wire interface from the high reference voltage to the low reference voltage, or from the low reference voltage to the high reference voltage.

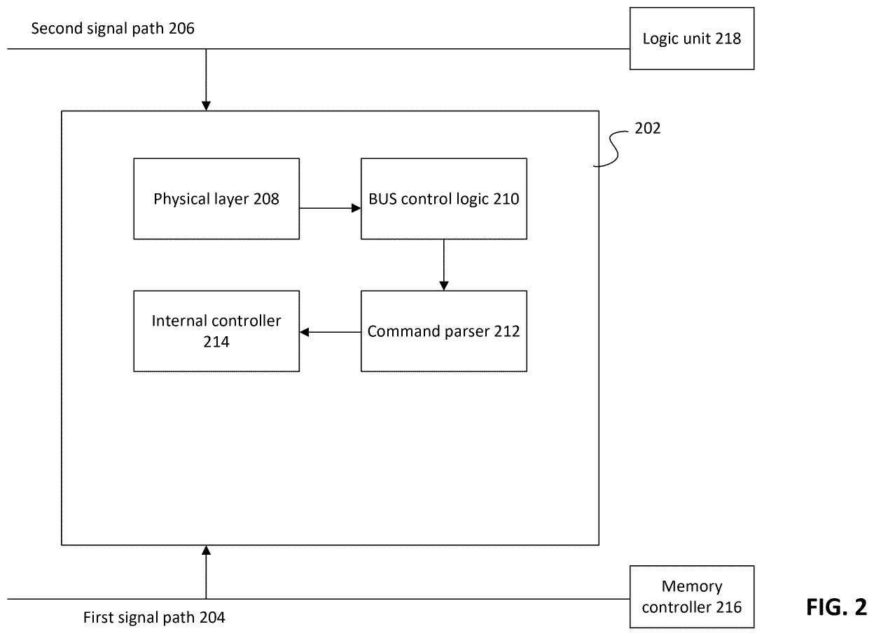

FIG. 2 depicts an optional configuration of a memory layer of the plurality of memory layers of the package 104. In this manner, the memory layer 202 is coupled to a first signal path 204, which may be a signal path between the memory and the memory controller. The memory layer 202 is also coupled to a second signal path 204, which may be a signal path between the logic unit and the various layers of the plurality of memory layers. Each memory layer of the plurality of memory layers may include any of a physical layer unit 208, configured to perform any of the tasks associated with the physical layer of the open systems interconnection (OSI) model, which may include the transmission and reception of raw bits over a physical data link; a BUS control logic 210, which may be configured to control the sending of signals across the second signal oath 206 (e.g., to prevent collision); a command parser 212, which may be or include a logic circuit (e.g. distinct from the “logic unit” as described throughout) that is configured to decode and parse commands received over the second signal interface; and an internal controller 214, which may be configured to route or connect to any portion of the memory layer based on an address, analyze a detected bit, store a bit, or otherwise.

In some embodiments, the apparatus may be configured without respect to the first signal path, such that the apparatus may be understood to include a memory, comprising a plurality of stacked memory layers, each stacked memory layer comprising a plurality of memory cells; and a logic unit, coupled to the memory via a second signal path, different from the first signal path that extends from the logic unit through each layer of the stacked memory layers; wherein the logic unit is configured to read a stored value from the memory, or to save a value to the memory, using the second signal path.

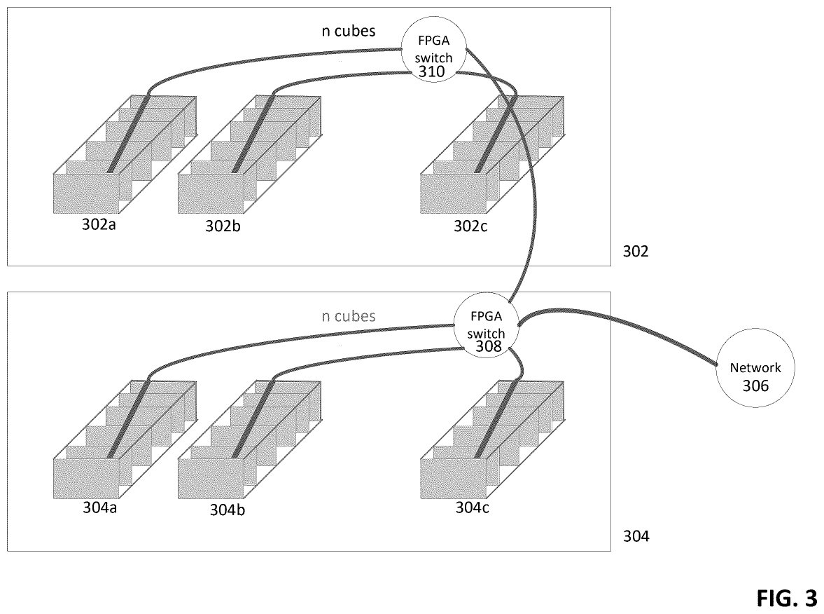

FIG. 3 depicts a system with multiple memory cubes. The figure depicts a first group of memory cubes 302, which includes memory cubes 302a, 302b, and 302c; and a second group of memory cubes 304, which includes memory cubes 304a, 304b, and 304c. The network 306 may access any of these above memory cubes by way of one or more switches, which are shown as a first switch 308 and a second switch 310. Of note, these switches are labeled as FGPA switches, but this is only for demonstrative purposes, and alternative switch types may be used. FGPA switch 308 is depicted as being able to switch to generate a connection between the network 306 and any one of memory cube 304a, memory cube 304b, memory cube 304c, or the second switch 310. Should the second switch 310 be selected, the second switch 310 may connect the network 306 to any one of memory cubes 302a, 302b, or 302c. In other words, clusters of memory cubes may be linked (e.g., daisy chained) together to permit access between the network 306 and any particular memory cube. The hardware combined with platform support, such as the FPGA switch and software driver depicted herein provides better memory management than conventional approaches.

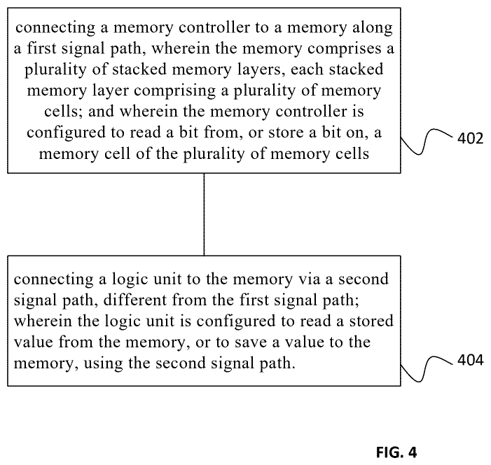

FIG. 4 depicts a method, comprising connecting a memory controller to a memory along a first signal path, wherein the memory comprises a plurality of stacked memory layers, each stacked memory layer comprising a plurality of memory cells; and wherein the memory controller is configured to read a bit from, or store a bit on, a memory cell of the plurality of memory cells 402; and connecting a logic unit to the memory via a second signal path, different from the first signal path; wherein the logic unit is configured to read a stored value from the memory, or to save a value to the memory, using the second signal path 404.

Further aspects will be disclosed by way of example:

In Example 1, an apparatus comprising: a memory, comprising a plurality of stacked memory layers, each stacked memory layer comprising a plurality of memory cells; a memory controller, coupled to the memory along a first signal path, and configured to read a bit from, or store a bit on, a memory cell of the plurality of memory cells; and a logic unit, coupled to the memory via a second signal path, different from the first signal path;
wherein the logic unit is configured to read a stored value from the memory, or to save a value to the memory, using the second signal path.

In Example 2, the apparatus of Example 1, wherein the second signal path is an electrically conductive path from the logic unit to each of the plurality of stacked memory layers.

In Example 3, the apparatus of Example 1 or 2, wherein the second signal path is a single wire interface.

In Example 4, the apparatus of Example 2 or 3, wherein the logic unit is configured to communicate with the memory using a single wire interface protocol.

In Example 5, the apparatus of Example 4, wherein single wire interface protocol comprises 1-Wire, Single Wire Protocol, Inter-Integrated Circuit Protocol (I3C), or Inter-Integrated Circuit Protocol (I2C).

In Example 6, the apparatus of Example 1, wherein the second signal path is a double wire interface.

In Example 7, the apparatus of Example 6, wherein the logic unit is configured to communicate with the memory using an Ethernet Protocol.

In Example 8, the apparatus of any one of Examples 1 to 7, wherein the second signal path is coupled to each of the plurality of stacked memory layers in series.

In Example 9, the apparatus of any one of Examples 1 to 8, wherein the logic unit comprises one of a field programmable gate array, a controller, or a processor.

In Example 10, the apparatus of Example any one of Examples 1 to 9, wherein the second signal path is an electrically conductive path from the logic unit to each of the plurality of stacked memory layers.

In Example 11, the apparatus of any one of Examples 1 to 10, wherein each stacked memory layer of the plurality of stacked memory layers comprises a BUS control logic, configured to determine when the logic unit or another stacked memory layer of the plurality of stacked memory layers is sending a signal, and not to send a signal when the logic unit or another stacked memory layer of the plurality of stacked memory layers is sending a signal.

In Example 12, the apparatus of any one of Examples 1 to 11, wherein each stacked memory layer of the plurality of stacked memory layers comprises a command parser, configured to receive a command from the logic unit over the second signal path, and to parse the signal.

In Example 13, the apparatus of Example 12, wherein parsing the signal comprises the command parser decoding an address corresponding to a stacked memory layer of the plurality of stacked memory layers.

In Example 14, the apparatus of Example 13, wherein parsing the signal comprises the command parser decoding an address corresponding to a memory cell of the plurality of memory cells.

In Example 15, the apparatus of any one of Examples 1 to 14, wherein the apparatus is a personal computer, a laptop computer, a tablet computer, a smartphone, or a wearable device.

In Example 16, an apparatus manufactured by a process comprising: connecting a memory controller to a memory along a first signal path, wherein the memory comprises a plurality of stacked memory layers, each stacked memory layer comprising a plurality of memory cells; and wherein the memory controller is configured to read a bit from, or store a bit on, a memory cell of the plurality of memory cells; and connecting a logic unit to the memory via a second signal path, different from the first signal path; wherein the logic unit is configured to read a stored value from the memory, or to save a value to the memory, using the second signal path.

In Example 17, the apparatus of Example 16, wherein the second signal path is an electrically conductive path from the logic unit to each of the plurality of stacked memory layers.

In Example 18, the apparatus of Example 16, wherein the second signal path is a single wire interface.

In Example 19, a method of manufacturing comprising: connecting a memory controller to a memory along a first signal path, wherein the memory comprises a plurality of stacked memory layers, each stacked memory layer comprising a plurality of memory cells; and wherein the memory controller is configured to read a bit from, or store a bit on, a memory cell of the plurality of memory cells; and connecting a logic unit to the memory via a second signal path, different from the first signal path; wherein the logic unit is configured to read a stored value from the memory, or to save a value to the memory, using the second signal path.

In Example 20, the method of Example 19, wherein the second signal path is an electrically conductive path from the logic unit to each of the plurality of stacked memory layers.

While the above descriptions and coupled figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An apparatus comprising:
a memory, comprising a plurality of stacked memory layers, each stacked memory layer comprising a plurality of memory cells;
a memory controller, coupled to the memory along a first signal path, and configured to read a bit from, or store a bit on, a memory cell of the plurality of memory cells; and
a logic unit, coupled to the memory via a second signal path, different from the first signal path;
wherein the logic unit is configured to read a stored value from the memory, or to save a value to the memory, using the second signal path.

2. The apparatus of claim 1, wherein the second signal path is an electrically conductive path from the logic unit to each of the plurality of stacked memory layers.

3. The apparatus of claim 1, wherein the second signal path is a single wire interface.

4. The apparatus of claim 2, wherein the logic unit is configured to communicate with the memory using a single wire interface protocol.

5. The apparatus of claim 4, wherein single wire interface protocol comprises 1-Wire, Single Wire Protocol, Inter-Integrated Circuit Protocol (I3C), or Inter-Integrated Circuit Protocol (I2C).

6. The apparatus of claim 1, wherein the second signal path is a double wire interface.

7. The apparatus of claim 6, wherein the logic unit is configured to communicate with the memory using an Ethernet Protocol.

8. The apparatus of claim 1, wherein the second signal path is coupled to each of the plurality of stacked memory layers in series.

9. The apparatus of claim 1, wherein the logic unit comprises one of a field programmable gate array, a controller, or a processor.

10. The apparatus of claim 1, wherein the second signal path is an electrically conductive path from the logic unit to each of the plurality of stacked memory layers.

11. The apparatus of claim 1, wherein each stacked memory layer of the plurality of stacked memory layers comprises a BUS control logic, configured to determine when the logic unit or another stacked memory layer of the plurality of stacked memory layers is sending a signal, and not to send a signal when the logic unit or another stacked memory layer of the plurality of stacked memory layers is sending a signal.

12. The apparatus of claim 1, wherein each stacked memory layer of the plurality of stacked memory layers comprises a command parser, configured to receive a command from the logic unit over the second signal path, and to parse the signal.

13. The apparatus of claim 12, wherein parsing the signal comprises the command parser decoding an address corresponding to a stacked memory layer of the plurality of stacked memory layers.

14. The apparatus of claim 13, wherein parsing the signal comprises the command parser decoding an address corresponding to a memory cell of the plurality of memory cells.

15. The apparatus of claim 1, wherein the apparatus is a personal computer, a laptop computer, a tablet computer, a smartphone, or a wearable device.

16. An apparatus manufactured by a process comprising:
coupling a memory controller to a memory along a first signal path, wherein the memory comprises a plurality of stacked memory layers, each stacked memory layer comprising a plurality of memory cells; and wherein the memory controller is configured to read a bit from, or store a bit on, a memory cell of the plurality of memory cells; and
coupling a logic unit to the memory via a second signal path, different from the first signal path; wherein the logic unit is configured to read a stored value from the memory, or to save a value to the memory, using the second signal path.

17. The apparatus of claim 16, wherein the second signal path is an electrically conductive path from the logic unit to each of the plurality of stacked memory layers.

18. The apparatus of claim 16, wherein the second signal path is a single wire interface.

19. A method of manufacturing comprising:
coupling a memory controller to a memory along a first signal path, wherein the memory comprises a plurality of stacked memory layers, each stacked memory layer comprising a plurality of memory cells; and wherein the memory controller is configured to read a bit from, or store a bit on, a memory cell of the plurality of memory cells; and
coupling a logic unit to the memory via a second signal path, different from the first signal path; wherein the logic unit is configured to read a stored value from the memory, or to save a value to the memory, using the second signal path.

20. The method of claim 19, wherein the second signal path is an electrically conductive path from the logic unit to each of the plurality of stacked memory layers.
